(19) United States
(12) Patent Application Publication
(10) Pub. No.: US 2015/0263229 A1
(43) Pub. Date: Sep. 17, 2015

(54) SEMICONDUCTOR LIGHT-EMITTING DEVICE AND METHOD OF MANUFACTURING THE SAME

(71) Applicant: KABUSHIKI KAISHA TOSHIBA, Tokyo (JP)

(72) Inventor: Kazuhiro AKIYAMA, Nomi Ishikawa (JP)

(21) Appl. No.: 14/475,527

(22) Filed: Sep. 2, 2014

(30) Foreign Application Priority Data
Mar. 14, 2014 (JP) 2014-051255

(51) Int. Cl. H01L 33/20; H01L 33/38; H01L 33/32; H01L 33/00

(52) U.S. Cl. CPC H01L 33/20; H01L 33/007; H01L 33/382; H01L 33/32; H01L 2933/0025

(57) ABSTRACT

A semiconductor light-emitting device includes a first-conductivity-type first semiconductor layer, a second-conductivity-type second semiconductor layer, a light-emitting layer provided between the first semiconductor layer and the second semiconductor layer, a nitride semiconductor layer that is provided on a side of the first semiconductor layer opposite to the light-emitting layer, has a resistance higher than a resistance of the first semiconductor layer, and includes recess portions communicating with the first semiconductor layer, and a conductive layer that comes into contact with the first semiconductor layer in the recess portions.

### CROSS-REFERENCE TO RELATED APPLICATION

This application is based upon and claims the benefit of priority from Japanese Patent Application No. 2014-051255, filed Mar. 14, 2014, the entire contents of which are incorporated herein by reference.

### FIELD

Embodiments described herein relate generally to a semiconductor light-emitting device and a method of manufacturing the same.

### BACKGROUND

In a manufacturing process of a semiconductor light-emitting device such as a light-emitting diode, there may be cases where an electrode has been formed on a surface from which a crystal growth substrate is removed. For example, in a case of crystal growth of a nitride semiconductor, a high electrical resistance buffer layer may be provided on a portion which comes into contact with the crystal growth substrate. After the crystal growth substrate is removed and the buffer layer is exposed, the buffer layer must generally be removed if electrode contact resistance in the device is to be acceptable. However, removing the buffer layer requires etching of the nitride semiconductor material forming the buffer layer and this etching takes a long time, resulting in a reduction in manufacturing throughput for the semiconductor light-emitting device. Furthermore, usually a chlorine gas is used for etching of the nitride semiconductor buffer material, and thus there is concern that the electrode properties may be altered or a contact resistance may increase due to the contamination by residual etch gas used to remove the buffer layer.

### DESCRIPTION OF THE DRAWINGS

FIG. 1 is a schematic cross-sectional view illustrating a semiconductor light-emitting device according to a first embodiment.

FIGS. 2A to 2C are schematic cross-sectional views illustrating a manufacturing process of the semiconductor light-emitting device according to the first embodiment.

FIGS. 3A to 3C are schematic cross-sectional views illustrating the manufacturing process subsequent to FIGS. 2A to 2C.

FIGS. 4A and 4B are schematic cross-sectional views illustrating the manufacturing process subsequent to FIGS. 3A to 3C.

FIG. 5 is a schematic cross-sectional view illustrating a semiconductor light-emitting device according to a modified example of the first embodiment.

FIGS. 6A to 6C are schematic cross-sectional views illustrating a manufacturing process of a semiconductor light-emitting device according to a second embodiment.

FIGS. 7A and 7B are schematic cross-sectional views illustrating the manufacturing process subsequent to FIGS. 6A to 6C.

FIGS. 8A and 8B are schematic cross-sectional views illustrating the manufacturing process subsequent to FIGS. 7A and 7B.

FIG. 9 is a schematic cross-sectional view illustrating the manufacturing process subsequent to FIGS. 8A and 8B.

### DETAILED DESCRIPTION

Embodiments described herein provide a semiconductor light-emitting device having a simplified manufacturing process and thus has high reliability, and a method of manufacturing the same.

In general, according to one embodiment, a semiconductor light-emitting device includes: a first-conductivity-type first semiconductor layer; a second-conductivity-type second semiconductor layer; a light-emitting layer provided between the first semiconductor layer and the second semiconductor layer; a nitride semiconductor layer that is provided on the first semiconductor layer has and having an electrical resistance higher than an electrical resistance of the first semiconductor layer, and includes recess portions communicating with the first semiconductor layer; and a conductive layer that comes into contact with the first semiconductor layer in the recess portions.

Hereinafter, exemplary embodiments will be described with reference to the drawings. Like elements in the drawings are denoted with the same reference numerals, and detailed description thereof will be appropriately omitted while only differences are described. In addition, the drawings are schematic or conceptual, and thus the relationship between thicknesses or widths of the elements and the ratio between the elements in size are not necessarily the same as those in practice. Moreover, even when the same elements are illustrated, the elements may be illustrated with different dimensions or ratios in the drawings.

### First Embodiment

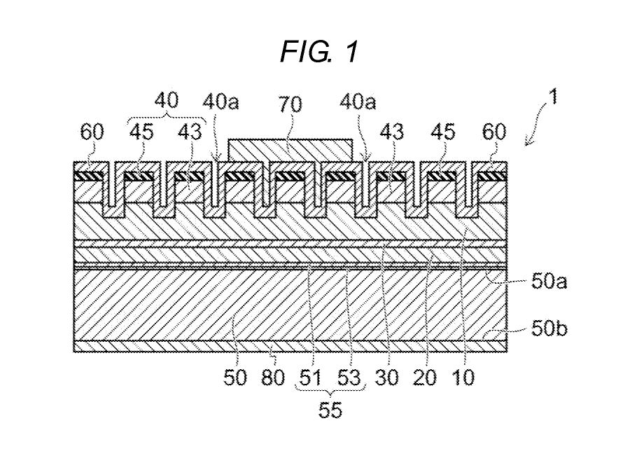

FIG. 1 is a schematic cross-sectional view illustrating a semiconductor light-emitting device 1 according to a first embodiment. The semiconductor light-emitting device 1 is, for example, a light-emitting diode (LED) which includes a nitride semiconductor as material.

The semiconductor light-emitting device 1 includes a first-conductivity-type first semiconductor layer (hereinafter, n-type semiconductor layer 10), a second-conductivity-type second semiconductor layer (hereinafter, p-type semiconductor layer 20), and a light-emitting layer 30. The light-emitting layer 30 is provided between the n-type semiconductor layer 10 and the p-type semiconductor layer 20.

The n-type semiconductor layer 10 is, for example, an n-type gallium nitride layer (GaN layer) and contains silicon (Si) as n-type impurities. The p-type semiconductor layer 20 is, for example, a p-type GaN layer and contains magnesium (Mg) as p-type impurities. The light-emitting layer 30 has at least one quantum well, and for example, and emits light having a wavelength of 450 nanometers (nm).

Here, the first-conductivity-type is described as n-type and the second-conductivity-type is described as p-type, but the embodiment is not limited thereto. The first-conductivity-type may be p-type and the second-conductivity-type may be n-type.

As illustrated in FIG. 1, the semiconductor light-emitting device 1 further includes a nitride semiconductor layer 40. The nitride semiconductor layer 40 is provided on the opposite side to the light-emitting layer 30 of the n-type semiconductor layer 10, and includes a first layer 43 and a second layer 45. The nitride semiconductor layer 40 has a higher resistance than that of the n-type semiconductor layer 10 and has recess portions 40a which communicate with the n-type semiconductor layer 10.

The first layer 43 is, for example, an undoped GaN layer. Here, “undoped” means that impurities are not doped by intention, and for example, unavoidably introduced impurities may be contained in a growth process of a GaN layer. The undoped GaN layer has, for example, a high resistance than an n-type GaN layer doped with n-type impurities.

The second layer 45 is, for example, an aluminum nitride layer (AlN layer). AlN is an insulator, and the second layer 45 is an insulating layer. In addition, the second layer 45 may include an AlGaN layer on a side that comes into contact with the first layer 43. The first layer 43 and the second layer 45 may be collectively called a buffer layer.

The recess portions 40a are, for example, grooves, and they divide the nitride semiconductor layer 40 into a plurality of portions. The recess portions 40a may also be a plurality of through-holes, rather than grooves of trenches, that penetrate through the nitride semiconductor layer 40.

Further, the semiconductor light-emitting device 1 includes a conductive layer 60 which comes into contact with the n-type semiconductor layer 10. As illustrated in FIG. 1, the conductive layer 60 covers the nitride semiconductor layer 40 and comes into contact with the n-type semiconductor layer in the recess portion 40a. The semiconductor light-emitting device 1 further includes an n-side pad electrode 70 which is selectively provided on the conductive layer 60.

In this disclosure, “cover” is not limited to a case where a “covering object” directly comes in contact with a “covered object” and may include a case of covering an object with another constituent element interposed therebetween.

The conductive layer 60 is, for example, a transparent film which transmits light emitted from the light-emitting layer 30. The conductive layer 60 is, for example, a metal oxide film such as indium tin oxide (ITO). The n-side pad electrode 70 has, for example, a structure in which a titanium film (Ti film) and an aluminum (Al) film are layered, and is used for a bonding pad of a metal wire.

The semiconductor light-emitting device 1 further includes a substrate 50 provided on the opposite side to the light-emitting layer 30 of the p-type semiconductor layer 20. As illustrated in FIG. 1, the substrate 50 is connected to the p-type semiconductor layer 20 via a bonding layer 55.

The bonding layer 55 includes, for example, a contact portion 51 and a bonding portion 53. The contact portion 51 comes into contact with the p-type semiconductor layer 20 to form an ohmic contact. The bonding portion 53 bonds the substrate 50 and the p-type semiconductor layer 20 to each other. The contact portion 51 preferably contains silver (Ag) and is formed to reflect light from the light-emitting layer 30. The bonding portion 53 is, for example, a gold-tin alloy (AuSn alloy). A barrier metal may be provided between the contact portion 51 and the bonding portion 53.

As the substrate 50, for example, a silicon substrate having electrical conductivity is used. A rear surface electrode 80 is provided on a rear surface 50b side of the substrate 50 which is opposite to a surface 50a thereof that comes into contact with the bonding layer 55. As the rear surface electrode 80, for example, a gold-germanium alloy (AuGe alloy) is used.

In the semiconductor light-emitting device 1, for example, a forward voltage is applied between the n-side pad electrode 70 and the rear surface electrode 80 to flow current so that the light-emitting layer 30 emits light. In addition, the semiconductor light-emitting device 1 emits the light to the outside.

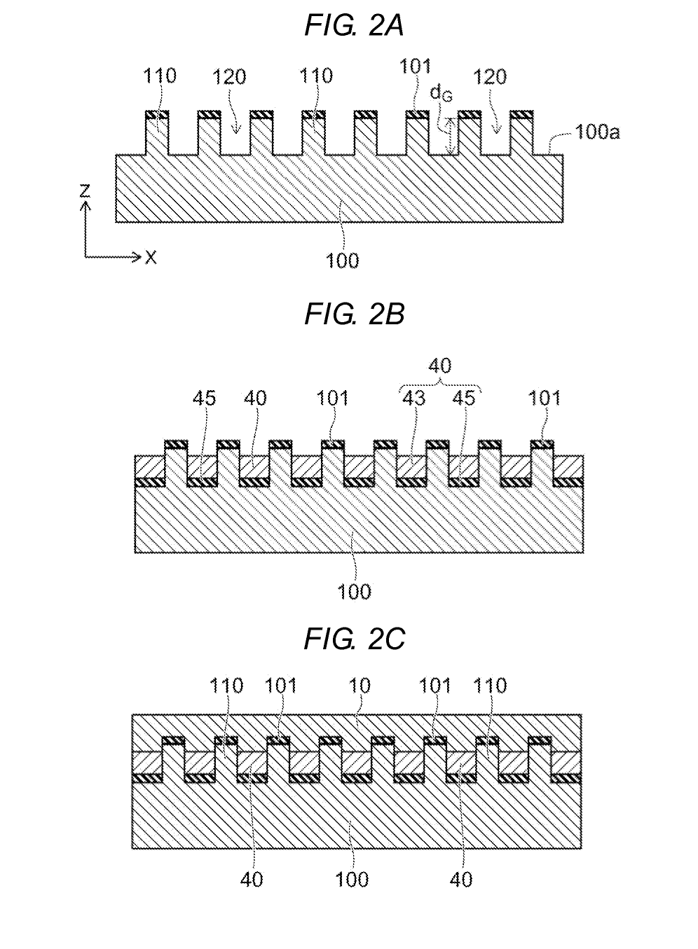

A method of manufacturing the semiconductor light-emitting device 1 according to the first embodiment will be described with reference to FIGS. 2A to 4B. FIGS. 2A to 4B are schematic cross-sectional views illustrating a manufacturing process of the semiconductor light-emitting device 1 according to the first embodiment.

A substrate 100 is prepared, and convex portions 110 are formed on the surface thereof. Convex portions 110 may be, for example, ridges or pillars. For example, the substrate 100 is selectively etched to form grooves 120. The convex portions 110 are thus formed between the grooves 120. The substrate 100 is, for example, a silicon substrate having a (111) face as the principal face. The grooves 120 are formed by, for example, selectively etching the (111) face using dry etching (e.g., reactive ion etching).

As illustrated in FIG. 2A, an insulating film 101 is formed on the convex portions 110. The insulating film 101 is, for example, a silicon oxide film. The substrate 100 may be selectively etched by using the insulating film 101 as an etching mask, or the insulating film 101 may be selectively formed on the convex portions 110 after forming the grooves 120. In addition, the grooves 120 are etched so that bottom surfaces 100a thereof become the (111) face.

Thereafter, as illustrated in FIG. 2B, the nitride semiconductor layer 40 is selectively formed inside the grooves 120 (in other words, in the vicinities of the convex portions 110). The nitride semiconductor layer 40 may be formed by using, for example, a metal organic chemical vapor deposition (MOCVD) method.

The nitride semiconductor layer 40 includes a second layer 45 that is directly formed on the (111) face of silicon. The second layer 45 relieves strain caused by lattice mismatch between the material of layer 40 (e.g., GaN) and the material of substrate 100 (e.g., silicon). As the second layer 45, for example, an AlN layer is used. The second layer 45 may also include, in some embodiments, an AlGaN layer formed on the AlN layer.

Subsequently, the first layer 43 of nitride semiconductor layer 40 is formed on the second layer 45. The first layer 43 is, for example, a GaN layer and is preferably grown without intentional incorporation of doping impurities. For example, a large number of crystal dislocations caused by lattice mismatch between the second layer 45 and the (111) face of silicon become integrated while the first layer 43 is grown, thereby reducing the number of crystal dislocations.

The first layer 43 and the second layer 45 are formed to, for example, override the crystal orientation of the (111) face of silicon. That is, the nitride semiconductor layer generally has a hexagonal crystal structure when grown and the c-axis thereof is aligned with the <111> axis of silicon crystal. Accordingly, the nitride semiconductor layer 40 may be selectively grown on the bottom surfaces 100a of the grooves 120 (in other words, in the vicinities of the convex portions 110).

It is preferable that the thickness of the nitride semiconductor layer 40 including the first layer 43 and the second layer 45 be less than a depth d_{G} of the groove 120. The depth d_{G} of the groove 120 is, for example, 1 to 2 micrometers (μm).

In this disclosure, unless otherwise specified, “thickness”, “height”, or “depth” means a distance in a direction perpendicular to the bottom surface 100a of the groove 120 (Z direction). In addition, “width” means a distance in the X direction perpendicular to the Z direction or a distance in the Y direction perpendicular to the X and Z directions.

Thereafter, as illustrated in FIG. 2C, the n-type semiconductor layer 10 which covers the convex portions 110 and the nitride semiconductor layer 40 is formed. The n-type semiconductor layer 10 is, for example, a GaN layer doped with silicon as n-type impurities.

At an initial stage of a process of forming the n-type semiconductor layer 10, the n-type semiconductor layer 10 is selectively formed on the nitride semiconductor layer 40. Since the insulating film 101 is formed on the convex portions 110, the n-type semiconductor layer 10 is not grown on the convex portions 110. The n-type semiconductor layer 10 is, for example, grown on the nitride semiconductor layer 40 in the c-axis direction (Z direction) thereof.

The n-type semiconductor layer 10 is eventually grown on the nitride semiconductor layer 40 to extend in the lateral direction (X direction) at a height higher than the upper surface of the insulating film 101. That is, so-called lateral growth begins. In addition, the n-type semiconductor layer 10 which grows above the nitride semiconductor layer 40 from the adjacent grooves 120 extends in the lateral direction and becomes continuous. Accordingly, the n-type semiconductor layer 10 may be formed on the convex portions 110 and the nitride semiconductor layer 40.

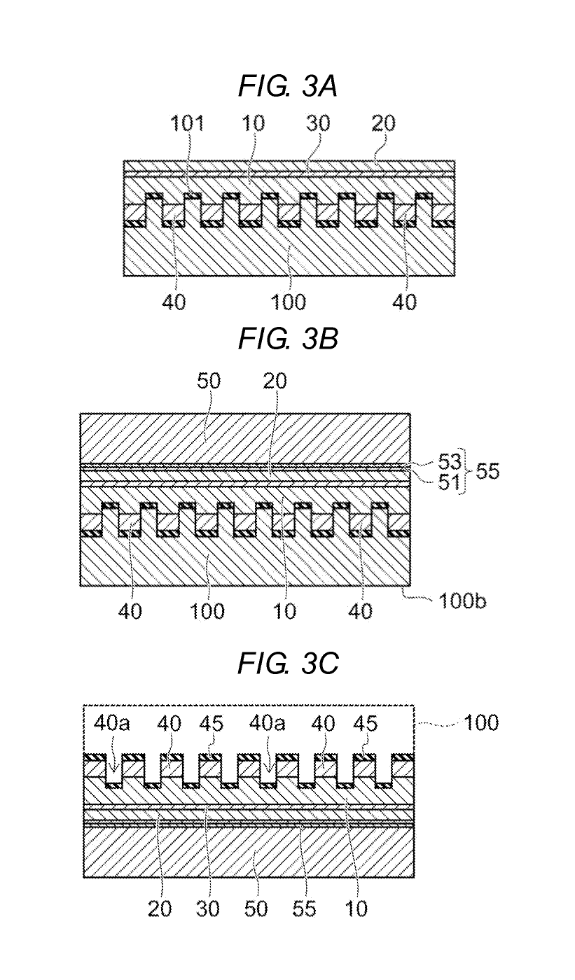

Thereafter, as illustrated in FIG. 3A, the light-emitting layer 30 is formed on the n-type semiconductor layer 10, and subsequently, the p-type semiconductor layer 20 is formed on the light-emitting layer 30.

The light-emitting layer 30 is, for example, formed to include one or more quantum wells having a GaN layer as a barrier layer and having an InGaN layer as a well layer. That is, the GaN barrier layer and the InGaN well layer are alternately layered to form the light-emitting layer 30. The GaN barrier layer is, for example, formed into a thickness of 10 to 20 nm, and the InGaN well layer is, for example, formed into a thickness of 3 to 5 nm. The InGaN layer contains, for example, 15% of In.

The p-type semiconductor layer 20 is, for example, a GaN layer containing magnesium (Mg) as p-type impurities. The p-type semiconductor layer 20 may include a p-type AlGaN layer in a portion that comes into contact with the light-emitting layer 30.

Thereafter, as illustrated in FIG. 3B, the substrate 50 is bonded onto the p-type semiconductor layer 20 via the bonding layer 55. The bonding layer 55 includes, for example, the contact portion 51 and the bonding portion 53. The contact portion 51 is, for example, a metal film containing Ag. The contact portion 51 forms an ohmic contact with the p-type semiconductor layer 20 and also functions as a reflection layer which reflects the light emitted from the light-emitting layer 30 in a direction toward the n-type semiconductor layer 10. The bonding portion 53 is a metal film containing an AuSn alloy and bonds the p-type semiconductor layer 20 and the substrate 50 to each other.

For example, the contact portion 51 is formed on the p-type semiconductor layer 20, and the bonding portion 53 is formed on the substrate 50. In addition, the substrate 50 and the substrate 100 are arranged to allow the contact portion 51 and the bonding portion 53 to face each other and come into contact with each other. Thereafter, the substrate 100 and the substrate 50 are maintained in a state of coming into contact with each other at a predetermined pressure, and the substrate 100 and the substrate 50 are heated at a temperature higher than the melting point of the bonding portion 53. Accordingly, the substrate 50 may be bonded onto the p-type semiconductor layer 20.

Thereafter, a rear surface 100b side of the substrate 100 is processed. For example, the rear surface 100b side of the substrate 100 is polished or ground to thin the substrate 100. Thereafter, the substrate 100 and the convex portions 110 thereof are selectively removed by, for example, wet etching. Accordingly, as illustrated in FIG. 3C, a structure in which the nitride semiconductor layer 40 remains on the n-type semiconductor layer 10 and the recess portions 40a are provided therebetween may be formed. The n-type semiconductor layer 10 is exposed at the bottom portion of the recess portion 40a, for example.

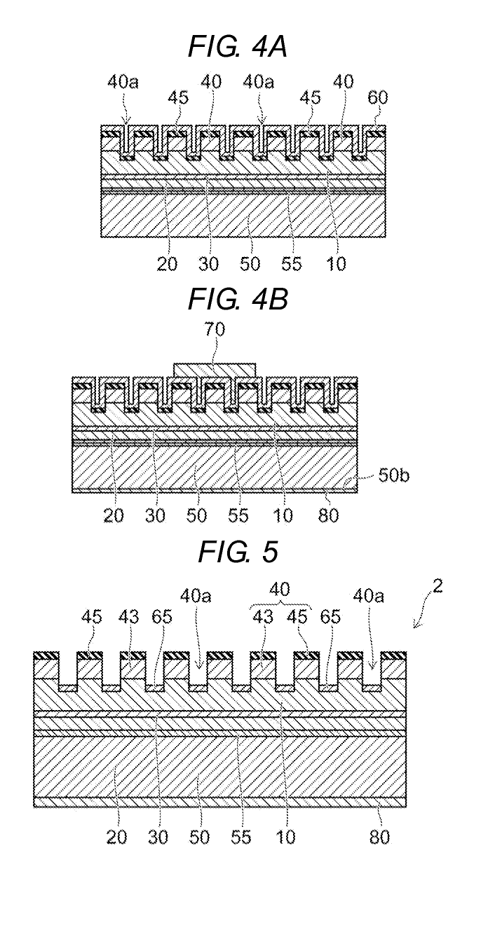

Thereafter, as illustrated in FIG. 4A, the conductive layer 60 is formed and comes into contact with the n-type semiconductor layer 10 exposed at the bottom portion of the recess portion 40a. The conductive layer 60 is, for example, a transparent electrode which uses ITO or the like, and may be formed using sputtering.

The conductive layer 60 is, for example, formed to cover the nitride semiconductor layer 40 and the bottom portion of the recess portion 40a. The nitride semiconductor layer 40 includes the first layer 43, which comes into contact with the n-type semiconductor layer 10, and the second layer 45, which is positioned on the upper surface side from which the substrate 100 is removed. Therefore, the conductive layer 60, for example, comes into contact with the second layer 45 including the AlN layer. In other words, the nitride semiconductor layer includes AlN in the portion that comes into contact with the conductive layer 60.

Thereafter, as illustrated in FIG. 4B, the n-side pad electrode 70 is selectively formed on the conductive layer 60. Subsequently, the rear surface electrode 80 which comes into contact with the rear surface 50b of the substrate 50 is formed, thereby completing the semiconductor light-emitting device 1.

As described above, in the manufacturing method according to this embodiment, the n-type semiconductor layer 10 may be exposed at the bottom portion of the recess portion 40a after the substrate 100 is removed. Therefore, without etching the nitride semiconductor layer 40 which is the buffer layer, the conductive layer 60 may be formed to contact the n-type semiconductor layer 10. Accordingly, simplification of the manufacturing process becomes possible, the manufacturing efficiency may be increased, and the manufacturing cost may be reduced.

In addition, any damage to the n-type semiconductor layer 10 which would be caused by the removal of the nitride semiconductor layer 40, for example, plasma damage caused by reactive ion etching (RIE) may be avoided, and thus the contact resistance of the n-side electrode may be reduced. Moreover, contamination by chlorine or the like by the process of dry-etching the nitride semiconductor layer 40 may be avoided, thereby enhancing the reliability of the semiconductor light-emitting device 1.

Furthermore, in this embodiment, since the conductive layer 60 contacts the n-type semiconductor layer 10 exposed on the convex portion of the recess portion 40a, it is possible to widen the overall contact area between electrode and n-type semiconductor layer 10. From this point of view, contact resistance may also be reduced.

Thereafter, a semiconductor light-emitting device 2 according to a modified example of this first embodiment will be described with reference to FIG. 5. FIG. 5 is a schematic cross-sectional view illustrating the semiconductor light-emitting device 2 according to the modified example of this first embodiment.

The semiconductor light-emitting device 2 is an LED which includes a nitride semiconductor as material, and includes the n-type semiconductor layer 10, the p-type semiconductor layer 20, and the light-emitting layer 30. The semiconductor light-emitting device 2 further includes the nitride semiconductor layer 40 provided on the opposite side to the light-emitting layer 30 of the n-type semiconductor layer 10. The nitride semiconductor layer 40 includes the first layer and the second layer 45. In addition, the nitride semiconductor layer 40 includes the recess portions 40a which communicate with the n-type semiconductor layer 10.

The semiconductor light-emitting device 2 includes a conductive layer 65 which comes into contact with the n-type semiconductor layer 10 exposed at the bottom portions of the recess portions 40a. The conductive layer 65 is selectively formed on the bottom portions of the recess portions 40a. In addition, the conductive layer 65 is formed so as not to cover the nitride semiconductor layer 40, that is, conductive layer 65 is formed only in bottom portions of the recess portions 40a. Light emitted from the light-emitting layer 30 is emitted to the outside via the nitride semiconductor layer 40. Therefore, as the conductive layer 65, a metal film which does not transmit the light emitted from the light-emitting layer 30 may be used. As a result, it is possible to reduce the spreading resistance of current that flows through the conductive layer 65, thereby enhancing the uniformity of light emission by the light-emitting layer 30.

### Second Embodiment

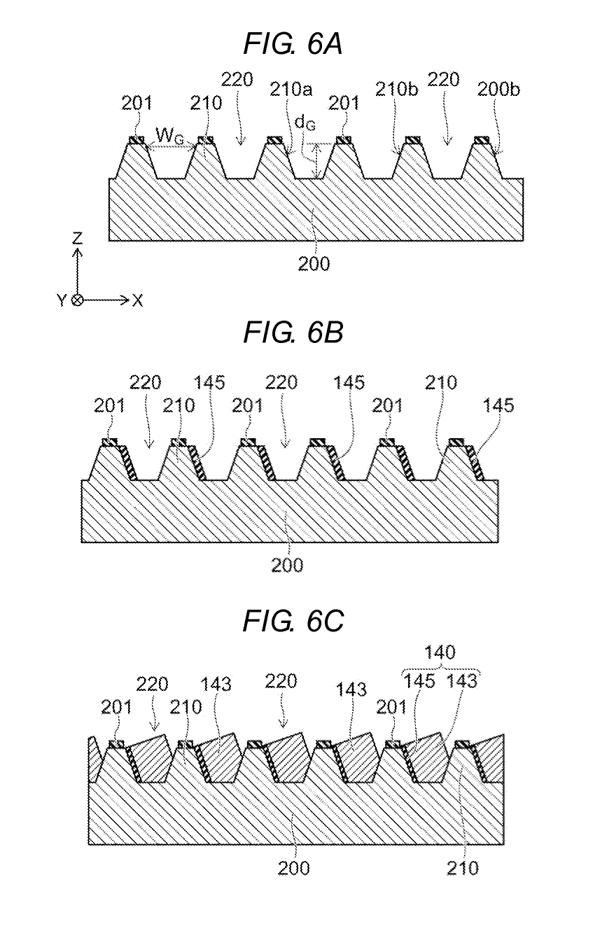

A method of manufacturing a semiconductor light-emitting device 3 according to a second embodiment will be described with reference to FIGS. 6A to 9. FIGS. 6A to 9 are schematic cross-sectional views illustrating a manufacturing process of the semiconductor light-emitting device 3 according to the second embodiment.

In this second embodiment, a substrate 200 is prepared, and convex portions 210 are formed on the surface thereof. The substrate 200 is, for example, a silicon substrate having a (100) face as the principal face. The convex portions 210 are formed by, for example, selectively performing anisotropic etching on the (100) face of silicon using a wet etching method. For example, a (111) face is exposed to one side surface 210a of the convex portion 210, and a (−1-11) face is exposed to the other side surface 210b thereof.

As illustrated in FIG. 6A, portions of the substrate 200 which are selectively etched become grooves 220. The convex portions 210 are formed between the grooves 220. The grooves 220 are provided, for example, in a stripe pattern extending in the Y direction illustrated in FIG. 6A.

An insulating film 201 is formed on the top surfaces of the convex portions 210. The insulating film 201 is, for example, a silicon oxide film. The substrate 200 may be selectively etched by using the insulating film 201 as an etching mask, or the insulating film 201 may be selectively formed on the convex portions 210 after forming the grooves 220. In addition, the insulating film 201 may be formed to cover the top surfaces and the side surfaces 210b of the convex portions 210.

Thereafter, a nitride semiconductor layer 140 is selectively formed inside the grooves 220 (in other words, in the vicinities of the convex portions 210). The nitride semiconductor layer 140 may be formed by using, for example, a MOCVD method.

As illustrated in FIG. 6B, a second layer 145 of the nitride semiconductor layer 140 is selectively formed on the side surfaces 210a of the convex portions 210. As the second layer 145, for example, an AlN layer is used. That is, the second layer 145 is formed by using conditions in which the AlN layer is selectively grown on the (111) face of silicon. An AlGaN layer may be formed on the AlN layer in some embodiments.

Subsequently, as illustrated in FIG. 6C, a first layer 143 of the nitride semiconductor layer 140 is formed on the second layer 145. The first layer 143 is, for example, a GaN layer and is preferably grown without including intentional dopants.

The first layer 143 and the second layer 145 are formed to, for example, override the crystal orientation of the (111) face of silicon. That is, the nitride semiconductor layer generally has hexagonal crystal structure when grown and the C-axis thereof is aligned with the <111> axis of silicon crystal. Accordingly, the nitride semiconductor layer 140 may be selectively grown on the side surfaces 210a of the convex portions 210. In addition, such selective growth may be achieved by covering the top surfaces and the side surfaces 210b of the convex portions 210 with an insulating film.

The depth d_{G} of the groove 220 is, for example, 1 to 2 micrometers (μm). The width W_{G} of the groove 220 is, for example, substantially equal to or greater than the thickness of the nitride semiconductor layer 140 (thickness in a direction perpendicular to the side surface 210a). The width W_{G} of the groove 220 is, for example, 1 to 2 μm, proximate to an upper surface of substrate 200. That is, the nitride semiconductor layer 140 is formed so as not to cover the convex portions 210.

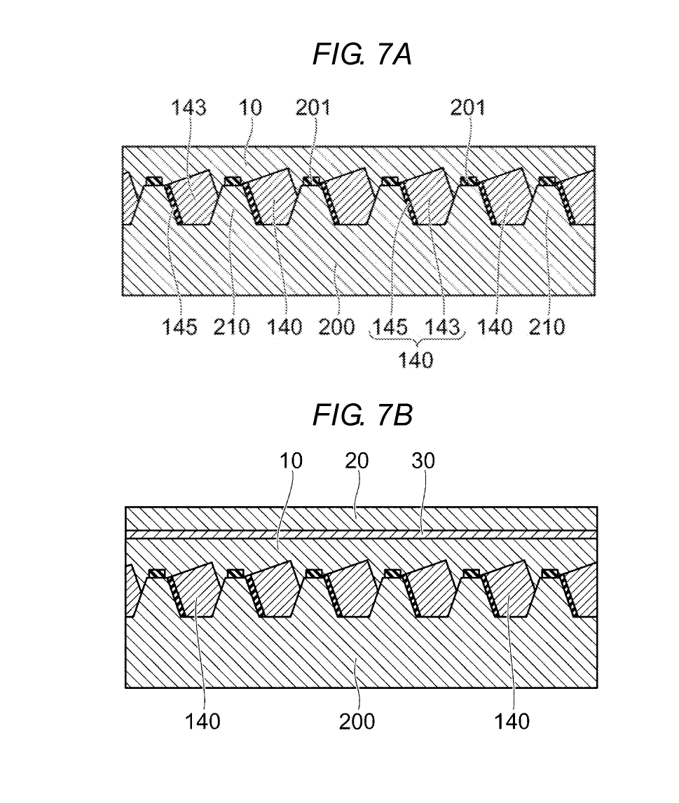

Thereafter, as illustrated in FIG. 7A, the n-type semiconductor layer 10 which covers the convex portions 210 and the nitride semiconductor layer 140 is formed. The n-type semiconductor layer 10 is, for example, a GaN layer doped with silicon as n-type impurities.

The n-type semiconductor layer 10 is grown, for example, in both the c-axis direction of the nitride semiconductor layer 140 (the direction perpendicular to the side surface 210a) and a direction perpendicular to the c-axis. In addition, the n-type semiconductor layer 10 which grows above the nitride semiconductor layer 140 from the adjacent grooves 220 extends in the lateral direction and becomes continuous. Accordingly, the n-type semiconductor layer 10 may be formed on the convex portions 210 and the nitride semiconductor layer 140.

Thereafter, as illustrated in FIG. 7B, the light-emitting layer 30 is formed on the n-type semiconductor layer 10, and subsequently, the p-type semiconductor layer 20 is formed on the light-emitting layer 30. The light-emitting layer 30 is, for example, formed to include one or more quantum wells having a GaN layer as a barrier layer and having an InGaN layer as a well layer.

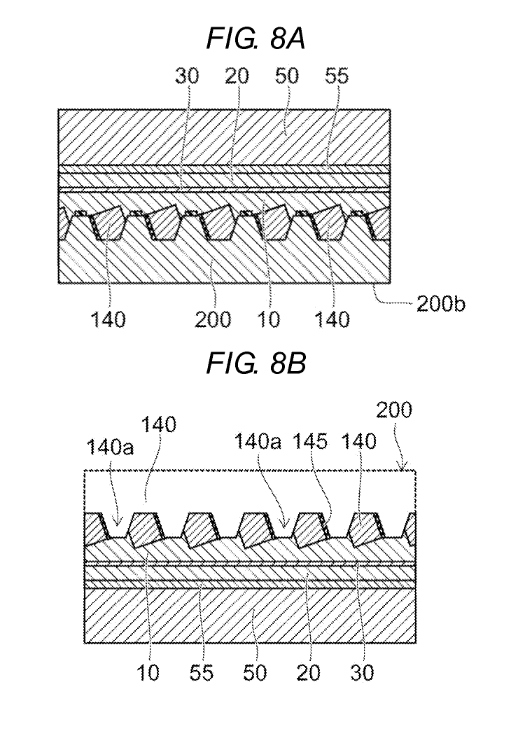

Thereafter, as illustrated in FIG. 8A, the substrate 50 is bonded onto the p-type semiconductor layer 20 via the bonding layer 55. The bonding layer 55 includes, for example, the contact portion 51 and the bonding portion 53 (see FIG. 3B).

Thereafter, a rear surface 200b side of the substrate 200 is processed. For example, the rear surface 200b side of the substrate 200 is polished or ground to thin the substrate 200. Thereafter, the substrate 200 and the convex portions 210 thereof are selectively removed by, for example, wet etching. Accordingly, as illustrated in FIG. 8B, a structure in which the nitride semiconductor layer 140 remains on the n-type semiconductor layer 10 and recess portions 140a are provided therebetween may be formed. The n-type semiconductor layer 10 is exposed at the bottom portion of the recess portion 140a.

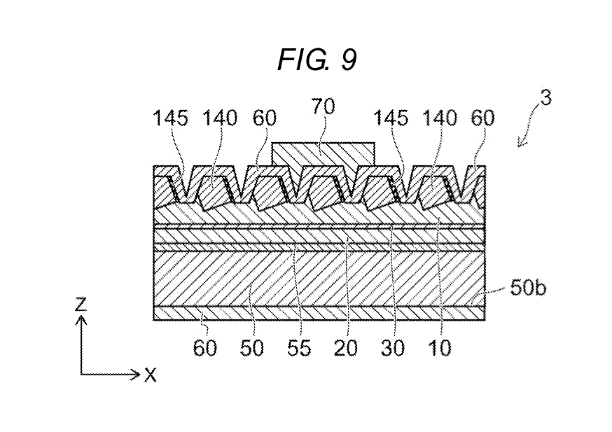

Thereafter, as illustrated in FIG. 9, the conductive layer 60 which comes into contact with the n-type semiconductor layer 10 exposed at the bottom portion of the recess portion 140a is formed. The conductive layer 60 is, for example, a transparent conductive material such as ITO or the like. Furthermore, the n-side pad electrode 70 is selectively formed on the conductive layer 60. Subsequently, the rear surface electrode 80 which comes into contact with the rear surface 50b of the substrate 50 is formed, thereby completing the semiconductor light-emitting device 1.

In this second embodiment, as the substrate 200 for the growth of nitride semiconductor, a silicon substrate having a (100) face as the principal face may be used. Even in this example, without etching the buffer layer, the conductive layer 60 which comes into contact with the n-type semiconductor layer 10 may be formed. Accordingly, the manufacturing process may be simplified, and thus it is possible to increase the manufacturing efficiency and reduce the manufacturing cost.

The crystal axis (Z axis in FIG. 9) of the light-emitting layer 30 formed in this second embodiment is inclined with respect to the c-axis. Accordingly, in the quantum well included in the light-emitting layer 30, piezoelectric polarization may be suppressed. In addition, the probability of light-emitting recombination between electrons and holes in the quantum well is increased, thereby increasing the emission efficiency of the light-emitting layer 30.

As described above, the semiconductor light-emitting devices 1 to 3 may have enhances characteristics and reliability. In addition, since etching of the buffer layer made of a nitride semiconductor is omitted, the manufacturing efficiency is increased, and thus the manufacturing cost may be reduced.

In this disclosure, the “nitride semiconductor” includes group III-V compound semiconductors of BₓIn_{y}Al_{z}Ga_{1-x-y-z}N (0≦x≦1, 0≦y≦1, 0≦z≦1, 0≦x++y+z≦1). Moreover, group V elements include, in addition to N (nitrogen), mixed crystal containing phosphorus (P), arsenic (As), and the like. In addition, a nitride semiconductor which further contains various types of elements added to control various properties such as the conductivity type, and a nitride semiconductor which further contains various types of elements that are included unintentionally may be included in the “nitride semiconductor”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device comprising:
a light-emitting layer between a first semiconductor layer of a first-conductivity type and a second semiconductor layer of a second-conductivity type;
a nitride semiconductor layer on the first semiconductor layer and having a resistance higher than a resistance of the first semiconductor layer; and
a conductive layer electrically contacting the first semiconductor layer within a plurality of recess portions in the nitride semiconductor layer.

2. The device according to claim 1, wherein the nitride semiconductor layer comprises an aluminum nitride portion which is in contact with the conductive layer.

3. The device according to claim 1, wherein the plurality of recess portions comprises grooves that divide the nitride semiconductor layer into a plurality of discrete portions.

4. The device according to claim 1, wherein the plurality of recess portions comprises holes.

5. The device according to claim 1, further comprising:
a substrate on a side of the second semiconductor layer opposite the light-emitting layer.

6. The device according to claim 1, wherein the conductive layer covers the nitride semiconductor layer.

7. The device according to claim 6, further comprising:
a pad electrode on the conductive layer, wherein
a portion of the pad electrode is provided in at least one recess portion in the plurality of recess portions.

8. The device according to claim 1, wherein the nitride semiconductor layer is provided in a plurality of portions by growing the nitride semiconductor layer on a plurality of portions of a silicon substrate having an exposed (111) crystal face, the (111) crystal face being exposed by wet etching a (100) crystal face of the silicon substrate.

9. The device according to claim 1, wherein the conductive layer is disposed on the first semiconductor layer at a bottom of each recess portion in the plurality of recess portions and does not directly contact the nitride semiconductor layer.

10. The device according to claim 1, wherein the conductive layer comprises indium tin oxide.

11. A method of manufacturing a light-emitting device, the method comprising:
etching a first substrate and forming protruding portions in the first substrate;
forming a nitride semiconductor layer adjacent to the protruding portions, the nitride semiconductor layer having an upper surface lower than an upper surface of the protruding portions;
forming a first-conductivity-type first semiconductor layer that covers the protruding portions and the nitride semiconductor layer, the nitride semiconductor layer having a resistance higher than the first-conductivity-type semiconductor layer;
forming a light-emitting layer on the first semiconductor layer;
forming a second-conductivity-type second semiconductor layer on the light-emitting layer;
bonding a second substrate to the second semiconductor layer;
removing the first substrate to form openings in the nitride semiconductor which expose portions of the first semiconductor layer; and
forming a conductive layer in the openings in the nitride semiconductor layer, the conductive layer electrically contacting exposed portions of first semiconductor layer.

12. The method of claim 11, further comprising:
forming a pad electrode in electrical contact with the conductive layer.

13. The method of claim 11, wherein the first substrate is a silicon substrate.

14. The method of claim 11, wherein the first substrate is a silicon substrate having (100) crystal face as a principal face, and the protrusion portions are formed by selectively etching the principal face using a wet etching method.

15. The method of claim 11, wherein the openings in the nitride semiconductor layer are circular holes.

16. The method of claim 11, wherein the openings in the nitride semiconductor layer are grooves.

17. The method of claim 11, wherein the nitride semiconductor layer comprises an AlGaN portion and a GaN portion.

18. A light-emitting device, comprising:
a light-emitting layer between a first semiconductor layer of a first-conductivity type and a second semiconductor layer of a second-conductivity type;
a nitride semiconductor material disposed on the first semiconductor layer, the nitride semiconductor material comprising an undoped GaN portion in direct contact with the first semiconductor layer and an AlGaN portion; and
a conductive material contacting the first semiconductor layer through a plurality of recesses in the nitride semiconductor material.

19. The light-emitting device of claim 18, wherein the plurality of recesses comprise grooves.

20. The light-emitting device of claim 18, wherein conductive material is transparent to a wavelength of light emitted by the light-emitting layer.
